(19) United States
(12) Patent Application Publication
(10) Pub. No.: US 2025/0329360 A1
(43) Pub. Date: Oct. 23, 2025

(54) STORAGE ARRAY AND WRITING METHOD THEREOF

(71) Applicant: PEKING UNIVERSITY, Beijing (CN)

(72) Inventors: Zongwei WANG, Beijing (CN); Yimao CAI, Beijing (CN); Yuhang YANG, Beijing (CN); Jingwei SUN, Beijing (CN)

(73) Assignee: PEKING UNIVERSITY, Beijing (CN)

(21) Appl. No.: 19/202,794

(22) Filed: May 8, 2025

(30) Foreign Application Priority Data
Mar. 8, 2024 (CN) 202410265933.7

(51) Int. Cl. G11C 7/22; G11C 7/18; G11C 8/14

(52) U.S. Cl. CPC G11C 7/22; G11C 7/18; G11C 8/14

(57) ABSTRACT

The present disclosure provides a storage array including storage cells, write word lines, read word lines, write bit lines, and read bit lines. The storage cells are arranged in a horizontal and a vertical direction to form a matrix structure with m rows and n columns. The storage cell includes a read transistor and a write transistor. A drain of the read transistor is connected to one read bit line. A source of the read transistor is connected to one read word line. A gate of the read transistor is connected to a drain of the write transistor to form an intermediate storage node. A gate of the write transistor is connected to one write word line. A source of the write transistor of a storage cell in the last row of the storage array is connected to one write bit line. A source of the write transistor of a storage cell in a non-last row is connected to the intermediate storage node of an adjacent storage cell in the next row of the same column.

### RELATED APPLICATIONS

The present disclosure claims priority to Chinese patent application NO. 202410265933.7, filed on Mar. 8, 2024, and entitled “HIGH-DENSITY STORAGE ARRAY AND OPERATING METHOD THEREFOR”, the content of which is hereby incorporated by reference in its entirety.

### TECHNICAL FIELD

The present disclosure relates to the technical fields of memories and Complementary Metal-Oxide-Semiconductor (CMOS) integrated circuits, particularly to a storage array and an operation method therefor.

### BACKGROUND

The rapid growth of information data volume in modern society has imposed relatively high requirements on existing memories. The existing memories can be mainly classified into volatile memories and non-volatile memories according to the retention time. The volatile memories include Static Random-Access Memories (SRAMs) and Dynamic Random-Access Memories (DRAMs), while the mainstream of the non-volatile memories is FLASH based on the Negative-AND (NAND) gate structure. However, NAND FLASH memories have technical problems such as high operating voltage and difficulty in scaling down, and DRAMs face the technical problem that capacitors are difficult to scale down in dimension.

### SUMMARY

The present disclosure provides a storage array, including storage cells, write word lines, read word lines, write bit lines, and read bit lines. The storage cells are arranged in a horizontal and a vertical direction to form a matrix structure with m rows and n columns. The storage array with m rows and n columns includes m write word lines, m read word lines, n write bit lines, and n read bit lines. Each of the storage cells includes a read transistor and a write transistor. A drain of the read transistor is connected to one read bit line. A source of the read transistor is connected to one read word line, and a gate of the read transistor is connected to a drain of the write transistor to form an intermediate storage node. A gate of the write transistor is connected to one write word line, a source of the write transistor of a storage cell in the last row of the storage array is connected to one write bit line, and a source of the write transistor of a storage cell of the storage array in a non-last row is connected to the intermediate storage node of an adjacent storage cell in a next row of the same column. The storage cells of the storage array in the same row share one write word line and one read word line. The write word line and the read word line are parallel to each other. The storage cells in the same column share one read bit line and one write bit line. Only the storage cell in the last row of each of the columns has a lead connected to the write bit line. The write bit line and the read bit line are parallel to each other.

In some embodiments, the read transistor and the write transistor of the storage array include low-leakage oxide semiconductor transistors.

The present disclosure also provides a writing method for a storage array. The storage array has m rows and n columns. The row numbers of the array from top to bottom are in descending order from m to 1. The column numbers of the array from left to right are in ascending order from 1 to n. When it is required to write any desired storage state into storage cells in the m rows, the mothed includes:
controlling voltages of m write word lines to simultaneously turn on write transistors of the storage cells in rows 1 to m;
controlling voltages of n write bit lines to write a desired storage state for row m into the storage cells in rows 1 to m;
controlling a voltage of a write word line corresponding to storage cells in row m to turn off write transistors of the storage cells in row m, while maintaining the write transistors of the storage cells in the rows 1 to m-1 in an on-state;
controlling the voltages of the n write bit lines to write a desired storage state for row m-1 into the storage cells in the rows 1 to m-1;
controlling a voltage of a write word line corresponding to the storage cells in row m-1 to turn off write transistors of the storage cells in row m-1, while maintaining write transistors of the storage cells in rows 1 to m-2 in the on-state;
controlling the voltages of the n write bit lines to write a desired storage state for row m-2 into the storage cells in the rows 1 to m-2; and
repeating the above steps to sequentially write a desired storage state into the storage cells in row m-3 to row 1, and completing a writing process in response to the storage cells in all rows being written with respective desired storage states, wherein at this time, all the write word lines in the storage array are grounded, and the write transistors of the storage cells in all rows are in an off-state.

Through the above operation steps, any desired storage state can be written into the storage cells in the m rows of the storage array.

The details of one or more embodiments of the present disclosure are elaborated in the accompanying drawings and descriptions below. Other features, objectives, and advantages of the present disclosure will become apparent according to the description, drawings, and claims.

### BRIEF DESCRIPTION OF THE DRAWINGS

FIG. 1 is a schematic structural view of a 2T0C storage cell in the related art of the present disclosure.

FIG. 2 is a schematic structural view of an array structure consisting of 2T0C storage cells in the related art of the present disclosure.

FIG. 3 is a schematic structural view of a storage array in the present disclosure.

FIG. 4 is a schematic structural view of an array having two rows and two columns in a specific embodiment of this disclosure.

FIG. 5 shows a first step of a writing method for an array having two rows and two columns in a specific embodiment of the present disclosure.

FIG. 6 shows a second step of a writing method for an array having two rows and two columns in a specific embodiment of the present disclosure.

FIG. 7 shows a third step of a writing method for an array having two rows and two columns in a specific embodiment of the present disclosure.

FIG. 8 shows a fourth step of a writing method for an array having two rows and two columns in a specific embodiment of the present disclosure.

### DETAILED DESCRIPTION

The present disclosure is further clearly and completely elaborated below through the specific embodiments in conjunction with the accompanying drawings.

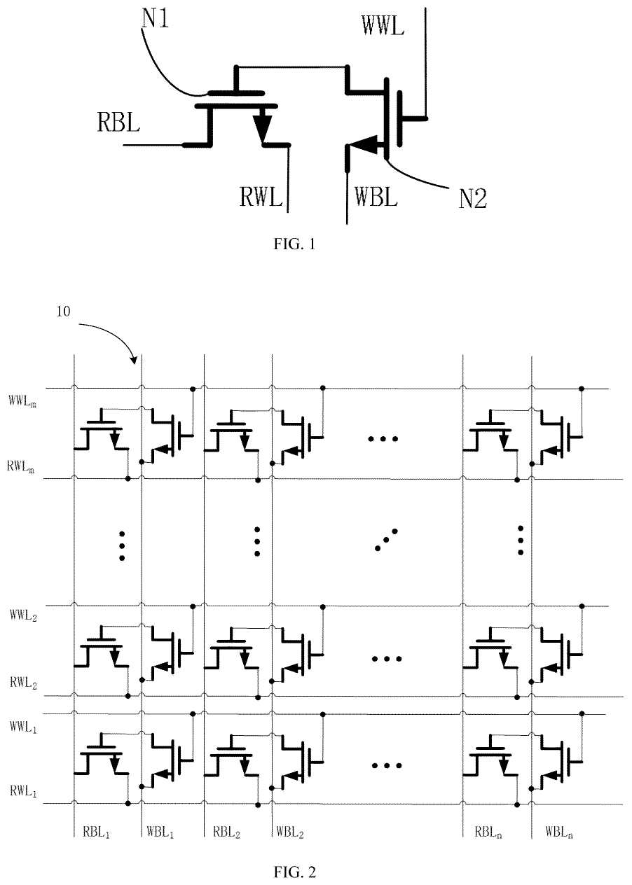

In the related art, FIG. 1 illustrates a structure of a 2T0C storage cell. This cell consists of two transistors, i.e., a read transistor N1 and a write transistor N2. The gate of the read transistor N1 is connected to the drain of the write transistor N2 to form an intermediate storage node. The source of the write transistor N2 is connected to the write bit line (WBL), and the gate is connected to the write word line (WWL). The drain and source of the read transistor N1 are respectively connected to the read bit line (RBL) and the read word line (RWL). When operating as a memory, this cell stores information by storing charges at the intermediate storage node. For example, when charges are present at the intermediate storage node, the gate voltage of the read transistor N1 is positive and the read transistor N1 is in an on-state, indicating that the stored information is 1. When no charges are stored at the intermediate storage node, the gate voltage of the read transistor N1 is zero and the read transistor N1 is in an off-state. At this time, the stored information in the memory is 0. FIG. 2 illustrates an array consisting of cells shown in FIG. 1. Cells in the same row share a WWL and an RWL and cells in the same column share an RBL and a WBL. Signal lines corresponding to those in FIG. 1 are labeled in FIG. 2. When a device needs to be written with data, the write transistor of the corresponding cell can be turned on through a signal of the WWL. The information to be stored can be written into the corresponding cell through a signal of the WBL. When reading data, a reading voltage can be applied to a cell to be read through a signal of the RWL. The reading can be accomplished by reading the current on the corresponding RBL.

However, the cell area of the 2T0C storage cell described above is relatively large. The main reason is that each cell needs to lead out four signal lines for connection to form an array, which limits the improvement of the density of the storage array. Therefore, it is of great significance to provide a storage array and a writing method therefor.

The present disclosure provides a storage array including storage cells, write word lines, read word lines, write bit lines, and read bit lines. A matrix structure with m rows and n columns is formed by the arrangement of storage cells in horizontal and vertical directions. Each of the storage cells includes a read transistor N1 and a write transistor N2. The drain of the read transistor N1 is connected to an RBL. The source of the read transistor N1 is connected to an RWL. The gate of the read transistor N1 is connected to the drain of the write transistor N2 to form an intermediate storage node. The gate of the write transistor N2 is connected to a WWL. The source of the write transistor N2 of a storage cell in the last row of the storage array is connected to a WBL. The source of the write transistor N2 of a storage cell in a non-last row of the storage array is connected to the intermediate storage node of the adjacent storage cell in the next row of the same column. In the storage array, storage cells in the same row share a WWL and an RWL. The WWL is parallel to the RWL. Storage cells in the same column share an RBL and a WBL. In each column, only the storage cell in the last row has a lead connected to the WBL. The WBL is parallel to the RBL. The storage array with m rows and n columns includes m WWLs, m RWLs, n WBLs, and n RBLs.

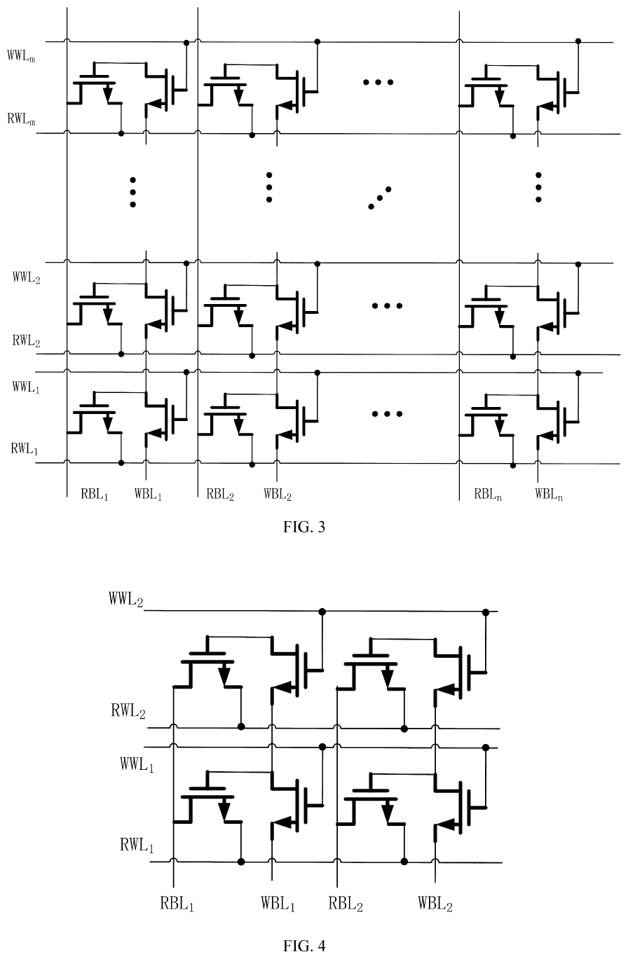

FIG. 3 is a schematic structural view of a storage array in the present disclosure. The storage array can be, for example, a high-density storage array. A circuit structure of the storage array is based on the 2T0C storage cell shown in FIG. 1. Each of the storage cells 10 includes a read transistor N1 and a write transistor N2. The gate of the read transistor N1 is connected to the drain of the write transistor N2 to form an intermediate storage node. The gate of the write transistor N2 is connected to a WWL. The drain and the source of the read transistor N1 are connected to an RBL and an RWL, respectively. The storage array in FIG. 3 is a storage array with m rows and n columns, and the names of the leads of different rows and columns are labeled in FIG. 3.

Different from the array structure shown in FIG. 2, in the array structure of the high-density storage array provided in the present disclosure shown in FIG. 3, from the first row to the (m-1)-st row, the drain of the write transistor N2 of each of the storage cells 10 is connected to the source of the write transistor N2 of the storage cell 10 in the next row of the same column. As such, the write transistors N2 of all the storage cells 10 in the same column are connected end to end to form a series structure. The source of the write transistor N2 of a storage cell 10 in the first row is connected to a WBL.

FIG. 4 illustrates a specific circuit implementation of the array structure shown in FIG. 3. The scale of the storage array is two rows and two columns. Oxide semiconductor transistors are selected to be the transistors in the storage array, such as low-leakage oxide semiconductor transistors. The name of each of the signal terminals is labeled in FIG. 4. The on-state and the off-state of a transistor represent storing 1 and 0, respectively. The VDD terminal and the GND terminal are used to represent the high level and low level in the circuit, respectively.

It is assumed that all the storage cells in FIG. 4 initially store data as 1, that is, the intermediate storage nodes of the four storage cells 10 are all in a charged state. When it is required to write the lower-row memories as “01” and the upper-row memories as “10”, that is, 1 is written into the two memories of the upper-left one and lower-right one, and 0 is written into the other two memories. The steps for writing are as follows.

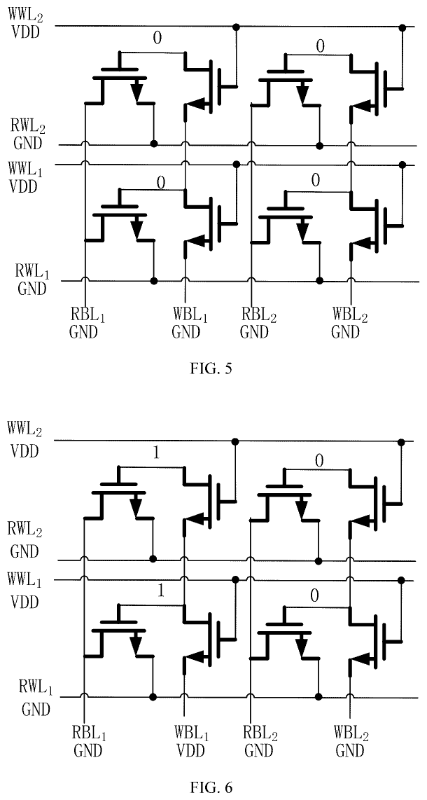

1. As shown in FIG. 5, the WWLs of the two rows are connected to VDD, and the remaining terminals are connected to GND. At this point, the write transistors of all the storage cells 10 in all rows are turned on and the storage states of all the storage cells are turned to 0.

2. As shown in FIG. 6, the WBL₁ is connected to VDD, and the WBL₂ is connected to GND. At this point, the storage states of the two memories in the left column are turned to 1 and the storage states of the two memories in the right column are turned to 0.

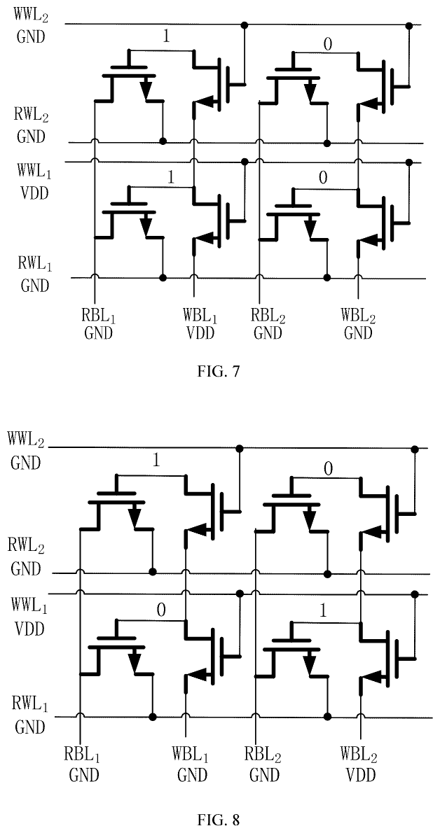

3. As shown in FIG. 7, the connection of the WWL₂ is changed from the VDD to GND. At this point, the write transistors of the second row are turned off and only the write transistors of the first row are turned on.

4. As shown in FIG. 8, the WBL₁ is connected to GND, and the WBL₂ is connected to VDD. At this point, the storage state of the lower-left memory is turned to 0. The storage state of the lower-right memory is turned to 1. At this point, all the write transistors are turned off and the writing is finished.

The above explains the writing method for a small-scale storage array having two rows and two columns. Those skilled in the art should understand that this array structure and operation method can be easily extended to large-scale storage arrays having multiple rows and columns to improve the throughput of the storage array.

Since the structure of the read transistor of the storage array provided in the present disclosure is the same as that of the array structure shown in FIG. 2, the reading method of the array shown in FIG. 2 can be used for reading. However, due to the change in the connection relationship of the write transistors, the writing method applicable to the array structure shown in FIG. 2 cannot write storage cells 10 in a certain row separately without affecting the storage states of the storage cells in other rows. Therefore, a writing method applicable to the storage array of the present disclosure is further provided. The storage array has m rows and n columns. The row numbers of the storage array from top to bottom are in descending order from m to 1 and the column numbers of the storage array from left to right are in ascending order from 1 to n. When it is required to write any desired storage state into the storage cells 10 in the m rows, the writing steps include:
controlling the voltages of WWL₁ to WWLₘ to simultaneously turn on the write transistors of the storage cells 10 in rows 1 to m;
controlling the voltages of WBL₁ to WBLₙ to write the storage state required for row m into the storage cells 10 in rows 1 to m;
controlling the voltage of WWLₘ to turn off the write transistors of the storage cells in row m, while maintaining the write transistors of the storage cells 10 in rows 1 to m-1 10 in the on-state;
controlling the voltages of WBL₁ to WBLₙ to write the desired storage state for row m-1 into the storage cells 10 in rows 1 to m-1;
controlling the voltage of WWLₘ₋₁ to turn off the write transistors of the storage cells 10 in row m-1, while maintaining the write transistors of the storage cells 10 in rows 1 to m-2 in the on-state;
controlling the voltages of WBL₁ to WBLₙ to write the desired storage state for row m-2 into the storage cells 10 in rows 1 to m-2; and
repeating the above steps to sequentially write the desired storage states into the storage cells 10 in row m-3, row m-4, . . . , row 2, and row 1. When all the storage cells 10 in all rows are written with the desired storage states, the writing process is completed. At this point, all the WWLs in the storage array are grounded, and the write transistors of the storage cells 10 in all rows are in the off-state.

Through the above steps, any desired storage state can be written into the storage cells in m rows of the storage array.

In the array structure, consisting of 2T0C storage cells, provided in an embodiment of the present disclosure, the source of the write transistor of a storage cell in non-last rows of the same column is directly connected to the intermediate storage node of the storage cell in an adjacent row to form a share structure instead of connecting the source thereof to a signal line of the storage array. Thus, the area required for leading out the sources of the write transistors of each storage cell in the existing 2T0C storage arrays is eliminated, which can reduce the area of the storage cells in the storage array to improve the storage density thereof.

Based on an embodiment of the present disclosure, the write transistors of two storage cells in adjacent rows can be directly connected. In the array structure of the related art, the source of the write transistor of each storage cell needs to be connected to a WBL and is required to be isolated from the drain of the write transistor of the storage cell in the adjacent row. Therefore, the array structure of the storage array provided in the present disclosure eliminates the area overhead caused by the isolation of the write transistors of storage cells in adjacent rows, which can reduce the area occupied by the storage cells to improve the storage density of the storage array. The writing required for the storage array can be implemented by the corresponding writing method provided in the present disclosure.

Finally, it should be noted that the purpose of disclosing the embodiments is to further understand the present disclosure. However, those skilled in the art can understand that various substitutions and modifications are feasible without departing from the essence and scope of the present disclosure and the appended claims. Therefore, the present disclosure should not be limited to the content disclosed in the embodiments, and the protection scope of the present disclosure is subject to the scope defined by the claims.

What is claimed is:

1. A storage array, comprising storage cells, write word lines, read word lines, write bit lines, and read bit lines, wherein the storage cells are arranged in a horizontal and a vertical direction to form an matrix structure with m rows and n columns, the storage array with m rows and n columns comprises m write word lines, m read word lines, n write bit lines, and n read bit lines, each of the storage cells comprises a read transistor and a write transistor, a drain of the read transistor is connected to one read bit line, a source of the read transistor is connected to one read word line, a gate of the read transistor is connected to a drain of the write transistor to form an intermediate storage node, a gate of the write transistor is connected to one write word line, a source of the write transistor of a storage cell in the last row of the storage array is connected to one write bit line, a source of the write transistor of a storage cell of the storage array in a non-last row is connected to the intermediate storage node of an adjacent storage cell in a next row of the same column, the storage cells of the storage array in the same row share one write word line and one read word line, the write word line and the read word line are parallel to each other, the storage cells in the same column share one read bit line and one write bit line, only the storage cell in the last row of each of the columns has a lead connected to the write bit line, and the write bit line and the read bit line are parallel to each other.

2. The storage array according to claim 1, wherein the read transistor and the write transistor of the storage array comprise low-leakage oxide semiconductor transistors.

3. A writing method for controlling a storage array according to claim 1, wherein the storage array has m rows and n columns, row numbers of the storage array from top to bottom are in descending order from m to 1 and column numbers of the storage array from left to right are in ascending order from 1 to n, and when it is required to write any desired storage state into storage cells in the m rows, steps of the method include:
controlling voltages of m write word lines to simultaneously turn on write transistors of the storage cells in rows 1 to m;
controlling voltages of n write bit lines to write a desired storage state for row m into the storage cells in rows 1 to m;
controlling a voltage of a write word line corresponding to storage cells in row m to turn off write transistors of the storage cells in row m, while maintaining write transistors of storage cells in rows 1 to m-1 in an on-state;
controlling the voltages of the n write bit lines to write a desired storage state for row m-1 into the storage cells in rows 1 to m-1;
controlling a voltage of a write word line corresponding to storage cells in row m-1 to turn off write transistors of the storage cells in row m-1, while maintaining write transistors of storage cells in rows 1 to m-2 in the on-state;
controlling the voltages of the n write bit lines to write a desired storage state for row m-2 into the storage cells in rows 1 to m-2; and
repeating the above steps to sequentially write desired storage states into storage cells in row m-3 to row 1, completing a writing process in response to the storage cells in all rows being written with respective desired storage states, wherein at this point, all the write word lines in the storage array are grounded, and the write transistors of the storage cells in all rows are in an off-state.
